(19) United States
(12) Patent Application Publication
(10) Pub. No.: US 2025/0138045 A1
(43) Pub. Date: May 1, 2025

(54) Acceleration Measurement System

(71) Applicant: The University of Sydney, Sydney, New South Wales (AU)

(72) Inventor: James Rabeau, Sydney, New South Wales (AU)

(73) Assignee: The University of Sydney, Sydney, New South Wales (AU)

(21) Appl. No.: 18/722,008

(22) PCT Filed: Dec. 21, 2022
(86) PCT No.: PCT/AU2022/051550

§ 371 Date: Jun. 20, 2024

(30) Foreign Application Priority Data
Dec. 21, 2021 (AU) 2021904174

(51) Int. Cl. G01P 15/093

(52) U.S. Cl. CPC G01P 15/093

(57) ABSTRACT

A system and method for measuring acceleration. The system comprises a diamond having a nitrogen-vacancy centre configured to emit fluorescence under optical illumination in presence of a radio frequency field tuned to a resonant frequency of the nitrogen-vacancy centre, and a magnet, wherein a distance between the magnet and the diamond varies in response to acceleration of the system, the change in distance altering a magnetic field experienced by the diamond. The system also comprises an optical sensor, the optical sensor configured to sense variation in fluorescence emitted by the diamond in response to the altered magnetic field for measuring acceleration.

This application claims Convention priority from Australian Provisional Patent Application No. 2021904174, filed 21 Dec. 2021, the contents of which are incorporated herein by reference in their entirety.

### TECHNICAL FIELD

The present invention relates generally to measurement of acceleration and, in particular, to measurement of acceleration using magnetic field sensitivity of a diamond.

### BACKGROUND

Measurement of acceleration is relevant to a wide range of industries. Acceleration measurement systems, also referred to as accelerometers, are used to measure acceleration for a wide variety of applications including navigation, location tracking, mining, military and medical applications.

Typically, commercial accelerometers are based on piezo-electrics, micro-electromechanical systems (MEMS) or quartz flexure systems. Implementations of accelerometers using each of piezo-electrics, MEMS and quartz flexures have limitations, depending on the application. Micro-g bias noise levels can be achieved in existing commercially available systems, however accuracy is limited by electromagnetic noise and vibrations, ultimately leading to drift in absolute measurement.

### SUMMARY

It is an object of the present invention to substantially overcome, or at least ameliorate, one or more disadvantages of existing arrangements.

According to a first aspect of the present disclosure there is provided a system for measuring acceleration, comprising: a diamond having a nitrogen-vacancy centre, whereby the diamond emits fluorescence under optical illumination in presence of a radio frequency field tuned to a resonant frequency of the nitrogen-vacancy centre, a magnet having a known mass; and an optical sensor; wherein the system is configured such that a distance between the magnet and the diamond varies in response to acceleration of the system, the change in distance altering a magnetic field experienced by the diamond; and the optical sensor is configured to sense variation in fluorescence emitted by the diamond in response to the altered magnetic field for measuring acceleration.

According to another aspect of the present disclosure, there is provided a method for measuring acceleration, comprising illuminating a diamond having a nitrogen-vacancy centre in presence of a radio frequency field tuned to a resonant frequency of the nitrogen-vacancy centre; measuring an initial magnetic field experienced by the diamond; sensing a variation in fluorescence emitted by the diamond if a distance between a magnet and the diamond varies in response to acceleration; generating, by an optical sensor, an electrical signal corresponding to the variation in fluorescence; determining using the generated signal, the acceleration.

According to another aspect of the present disclosure, there is provided a method for measuring acceleration, comprising: illuminating a diamond of the system of the above aspect in presence of a radio frequency field tuned to a resonant frequency of the nitrogen-vacancy centre; measuring an initial magnetic field experienced by the diamond; sensing a variation in fluorescence emitted by the diamond if a distance between the magnet and the diamond varies; generating, by an optical sensor, an electrical signal corresponding to the variation in fluorescence; determining using the generated signal, acceleration of the system.

Other aspects also disclosed.

### BRIEF DESCRIPTION OF THE DRAWINGS

At least one example embodiment of the present invention will now be described with reference to the drawings, in which:

FIG. 1A shows an example accelerometer system;

FIG. 1B shows an example architecture of an acceleration sensor system of the accelerometer system of FIG. 1A;

FIG. 2 shows an architecture of a control and readout system of the system of FIG. 1A;

FIG. 3 shows a flowchart describing operation of the acceleration measurement system;

FIG. 4A shows a graph of a relationship between flux density and acceleration;

FIG. 4B shows an enlarged portion of the graph of FIG. 4A;

FIG. 5 shows an example of operation of the sensor of the acceleration sensor system;

FIG. 6 shows an alternative architecture of the acceleration sensor system of FIG. 1A;

FIG. 7A shows another alternative architecture of the acceleration sensor system of FIG. 1A;

FIG. 7B shows an alternative architecture to the architecture of FIG. 7A;

FIG. 8 shows another alternative architecture of the acceleration sensor system of FIG. 1A;

FIGS. 9A and 9B collectively form a schematic block diagram representation of an electronic device upon which described arrangements can be practised; and

FIG. 10 shows a set of crystal structures of nitrogen vacancy centre diamond.

Detailed Description including Best Mode

Where reference is made in any one or more of the accompanying drawings to steps and/or features, which have the same reference numerals, those steps and/or features have for the purposes of this description the same function(s) or operation(s), unless the contrary intention appears.

The arrangements described herein relate to using magnetic field sensitivity of certain diamond structures to measure acceleration.

Diamond can in some instances contain a defect in the diamond's carbon crystal lattice, also referred to as a nitrogen-vacancy centre (NV centre). Properties relating to nitrogen-vacancy centres have been studied in both research and industry and found to include properties that make diamond a viable candidate for quantum technology applications including quantum computing, quantum sensing and quantum communication.

One of the properties of nitrogen-vacancy centre diamond is that a magnetic field will change frequencies of the diamond's magnetic resonance features due to a phenomenon known as Zeeman splitting. The change in magnetic resonance can be quantified by detecting magnetic resonance frequencies using optical illumination, for example using a laser or other optical illumination, while also applying a frequency tuneable radio-frequency field through the magnetic resonance spectrum. The technique of detecting magnetic resonance frequencies using a diamond with a nitrogen-vacancy centre under optical illumination while in presence of external radio-frequency and magnetic fields is known as optically detected magnetic resonance. The position of the magnetic resonance features in the spectrum relates to the strength of a magnetic field influencing the nitrogen-vacancy centre. A diamond with nitrogen-vacancy centre can thus be used as a magnetic field sensor.

The arrangements described use the magnetic field sensing properties of diamond with a nitrogen-vacancy centre to measure acceleration.

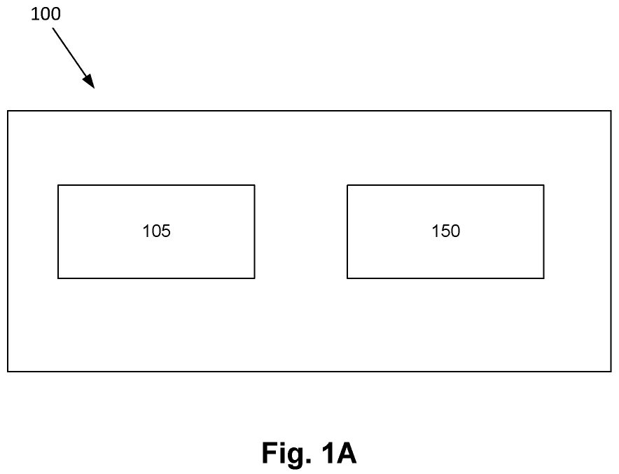

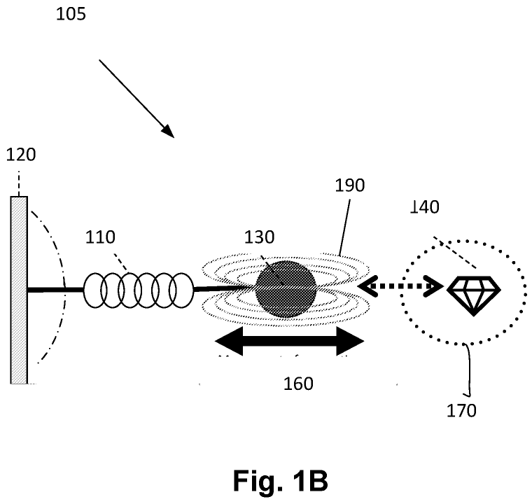

FIG. 1A shows an example acceleration measurement system 100. The system 100 comprises an acceleration sensor system 105 and a control and readout system 150. The system 100 can be implemented as a standalone accelerometer system (such as integrated to a single printed circuit board), or may comprise one or more components. For example, the control and readout system 150 could be implemented on an FPGA board, a microchip or remotely on a cloud computing device and the system 105 could be implemented as a standalone chip capable of communicating data to one or more components of the control and readout system 150.

FIG. 1B shows an example architecture of the acceleration sensor system 105. In the example of FIG. 1B, the sensor system 105 comprises a spring 110, a magnet 130 and a diamond sensing element 140 (also referred to as a diamond or diamond sensor). The acceleration sensor system 105 can be implemented as a standalone integrated system (such as integrated to a single microchip), or may comprise one or more components, for example.

The spring 110 is attached to a fixed point, for example a point 120, formed by at least part of the system 100. The spring 110 can be a resilient member or body, typically coiled or structured as a cantilever composed of a material which deforms or changes shape (for example contracts or elongates) under a net applied force, for example forces applied thereto due to acceleration. The change in shape of the spring can also be referred to as oscillation of the spring. The material from which the spring 110 is formed exerts a restorative force that allows the spring 110 to return toward an original shape as the force balances or is reduced. The spring 110 can be any type of spring suitable for use in acceleration measurement systems. Traditional acceleration measurement systems with a spring arrangement can use micro-electromechanical systems, for example a micro-fabricated cantilever in silicon or the like. The spring 110 has freedom of movement as forces due to acceleration are applied. In particular, the freedom of movement of the spring 110 allows for movement of the mass 130 to be measured along a plane (a direction or dimension) 160 relative to the fixed point 120. In the example system 100, the fixed point 120 relates to a surface. The surface 120 can be any fixed point to which the spring 110 may be affixed. For example, the fixed surface 120 may relate to a wall or an edge of a component of the system 100 if a standalone system.

The magnet 130 has a known mass or weight m and is attached to an end of the spring 110 in the example of FIG. 1A. If the system 100 accelerates, for example the system 100 is attached to an object accelerating or decelerating in a direction affecting forces applied along the plane 160, the spring 110 deforms (for example compresses, extends, bends or the like) and the mass 130 moves a distance resulting from the deformation. The distance is dependent on the magnitude and direction of the acceleration. As the spring 110 contracts or elongates as a result of the acceleration, a distance between the magnet 130 and the diamond 140 is altered or changed. The mass m of the magnet 130 can be selected based a spring constant k of the spring 110 and the magnitude of acceleration that is likely to require measurement. The magnet 130 can be formed from any ferromagnetic material whose motion can affect a surrounding magnetic field, such as iron, nickel and cobalt and the like.

The diamond sensor 140 can be formed from any diamond material containing at least one nitrogen-vacancy centre (hereinafter referred to as a diamond having a nitrogen-vacancy centre regardless of the number of nitrogen-vacancy centres). The diamond sensor 140 can be in form of a single crystal for example, such as crystals commercially available from elementsix™.

The control and readout system 150 is configured to control operation of the acceleration sensor 105 by irradiating the diamond sensor 140 with a radio frequency (RF field) field 170. The system 150 also performs control operations by illuminating the diamond sensor 140 such that fluorescence generated by the diamond sensor 140 when irradiated by the field 170 varies with changes in a magnetic field 190 (due to the magnet 130) experienced by the diamond 140. The control system 150 is also configured to receive readings from the sensor 105, typically to sense changes in fluorescence emitted by the diamond sensor 140 due to variations in the magnetic field 190 experienced by the diamond for determining an acceleration reading. The control and readout system 150 may in some implementations relate to an integrated microchip which can be used with the diamond sensor 140, for example attached to or integrated with the acceleration sensor system 105.

In an example implementation, the spring 110 has a Hooke's constant k=10 N/m and the magnet 130 has a mass m of 0.01 kg. In one example, a range of movement D of the magnet 130 relative to the diamond sensor is from 0 mm to 10 mm. The range of movement D can vary depending on the constant k of the spring 110 and the mass of the magnet 130 for example and/or the how the acceleration system 100 is implemented (for example using a board or as a microchip).

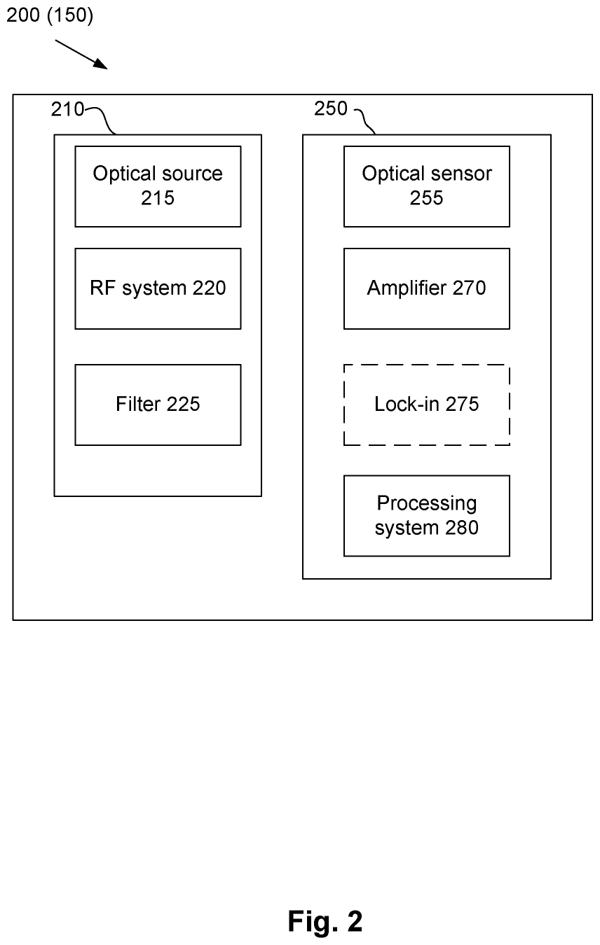

FIG. 2 shows an example architecture 200 of the control and readout system 150. In the example of FIG. 2, the system 150 is divided into two components-a control arrangement 210 and a sensing arrangement 250. The arrangements 210 and 250 can be integral to the same device, for example a single chip or circuit board or may be separate devices.

The control arrangement 210 includes an optical source 215, an RF (radio frequency) system 220 and a filter 225. The optical source 215 is configured to emit suitable optical illumination to stimulate fluorescence from the nitrogen-vacancy centre(s) in the diamond sensor 140 when in presence of a suitable RF magnetic field, such as the field 170. For example, the optical source can be a laser diode or light emitting diode or any other optical source suitable for stimulating fluorescence from a nitrogen-vacancy (NV) centre(s).

The RF system 220 generates microwave radiation having a frequency corresponding to magnetic resonance of the NV centre of the diamond sensor 140 and can typically be tuned to the resonant frequency. A suitable frequency to control electron spin is typically in a region of 2.88 GHz. The RF system 220 could for example be a voltage-controlled oscillator and amplifier built in to a control chip or built independently. By applying an appropriate frequency of RF radiation corresponding to the energy spacing between the 0 and +/−1 spin levels of the NV centres of the diamond 140 (approximately 2.88 GHZ), while measuring the fluorescence intensity generated by laser excitation (for example by the optical source 215), a change in fluorescence can be measured when a change in magnetic field experienced by the diamond sensor 140 occurs. The change in fluorescence is a signature of the magnetic resonance spectrum of the NV centres of the diamond sensor 140. Under the influence of an external magnetic field (such as the field) 190 the +/−1 spin sublevels change from being degenerate in energy to having different energies. The stronger the magnetic field 190, the more separated in energy the spin levels become. The separation of energy in spin levels with increasing magnetic field is known as Zeeman splitting. Zeeman splitting can be quantified by detecting where the decrease in fluorescence occurs when applying an RF field 170 with an appropriate frequency, typically around 2.88 GHz.

The optical filter 225 is used to filter the light emitted by the optical source 215. For example, the filter 225 can be used to remove light with a wavelength in the region of 532 nm. The filter 225 can also be used to prevent unwanted wavelengths illuminating a sensor of the readout arrangement 250, as described hereafter.

The readout arrangement 250 includes at least one optical sensor 255, a signal amplifier 270, a lock-in stage 275 and a data processing system 280.

The at least one optical sensor 255 is configured to sense fluorescence emitted due to the NV centres of the diamond 140. For example, in FIG. 2 the at least one optical sensor 255 can be a single silicon photodiode or other optical detector able to detect light in the visible and near infrared region of the optical spectrum. The filter 225 can in some instances be used to filter wavelengths of light received by the optical sensor 255. The filter 225 would be selected to filter out light that is outside of the spectral range of the nitrogen-vacancy centre, typically from 550 nm to 850 nm

Fluorescent light emitted by the diamond sensor 140 illuminates the optical sensor 255. As the fluorescence changes in power, an electrical signal generated by the optical sensor 255 changes in a corresponding manner. For example, a voltage of a circuit that includes the optical sensor 255 can vary correspondingly with the fluorescence.

The amplifier 270 is configured to amplify the electrical signal generated by the optical sensor 255 in order to facilitate signal measurement. The amplifier 270 can be any amplifier suitable to receive and amplify an electrical signal to improve a signal to noise ratio of the electrical signal.

The lock-in amplifier 275 is configured to remove noise and extract or determine a carrier signal representing the variation in signal generated by the optical sensor 255 using the output of the amplifier 270. The lock-in amplifier 275 can be omitted in some implementations, as indicated using broken lines. The lock-in amplifier can provide a benefit in some implementations of reducing noise in the signal generated by the amplifier 270.

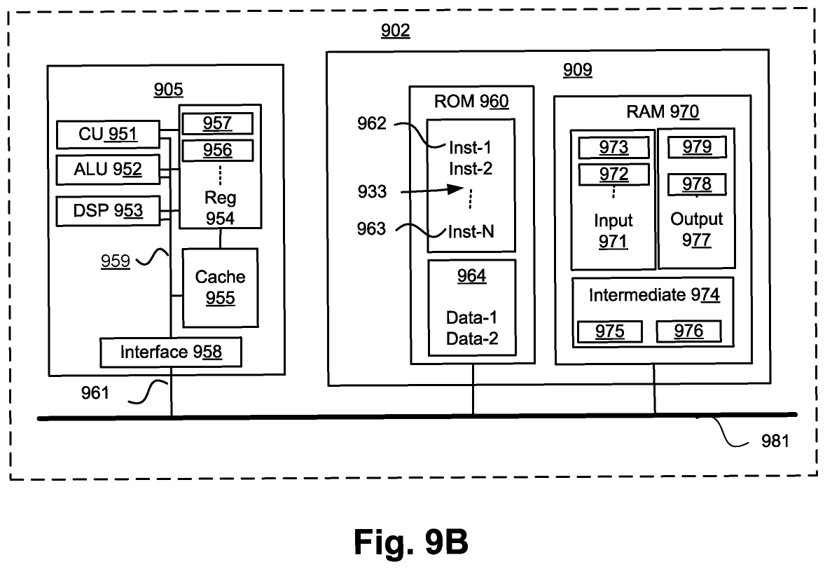

The processing system 280 can be implemented in hardware or software, or a combination thereof, for example as software stored for execution on a microprocessor. In some implementations, the processing system 280 can be implemented in an integrated manner with other components of the arrangement 250, for example as a component of a chip or circuit board arrangement. In other implementations, the processing system 280 can be separate to the system 100, for example based in a mobile device or cloud server. FIGS. 9A and 9B show an example implementation of the processing system 280 that is separate to other components of the arrangement 250.

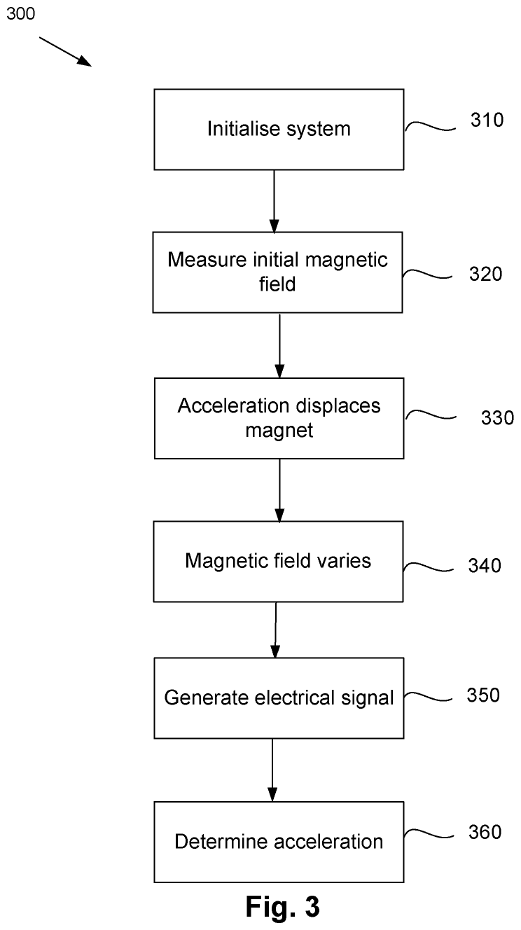

FIG. 3 shows a flowchart illustrating a dataflow 300 of measuring acceleration using the accelerometer system 100. The dataflow 300 starts at an initialising step 310. At step 310 the optical source 215 and the RF system 220 are switched on. The RF system 220 generates the RF field 170, at a frequency around 2.88 GHz that corresponds to the frequency of the NV centre of the diamond sensor 140. The optical source 215 generates an optical signal, for example a 532 nm, 100 mW laser signal, and transmits the laser signal to illuminate the diamond sensor 140. The laser signal and presence of the magnetic field cause the diamond sensor 140 to emit fluorescence.

The dataflow 300 continues from step 310 to an initial magnetic field measurement step 320. At step 320 an initial magnetic field (for example the field 190) experienced by the diamond 140 is measured. The initial magnetic field is caused by the (initially stationary) magnet 130 and is measured in terms of the strength of the fluorescence emitted by the diamond 140 and the position of the magnetic resonance features of the nitrogen vacancy centres in the diamond, as revealed by applying the RF field to the diamond and observing the RF frequencies at which the optical signal decreases. The initial magnetic field can depend mainly on the magnetic field strength from the magnet 130 plus any background magnetic fields from the environment.

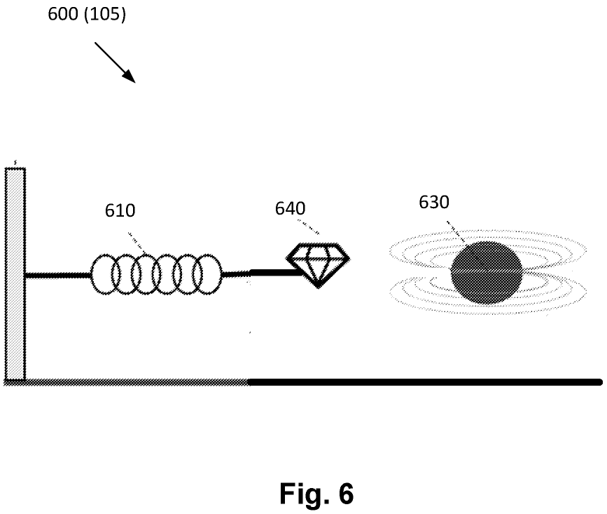

For example, FIG. 5 shows example 500 of operation of the acceleration sensor system 105. In the example 500 an initial magnetic field B_{ref} is determined in terms of a voltage Vref measured at the optical sensor 255 based on an initial position of a magnet 530 on a spring 510. The magnet 530 is equivalent to the magnet 130 and the spring 510 is equivalent to the spring 110. The initial position of the magnet 530 is a distance d_{ref} from a diamond sensor 540 (equivalent to the diamond sensor 140).

Returning to FIG. 3, the dataflow 300 continues from step 320 to an acceleration step 330. At step 330 the system 100 is subject to acceleration. For example, a host vehicle to which the system 100 is attached accelerates in a direction relevant to the plane 160. The acceleration causes the spring 110 to deform relative to the diamond sensor 140, for example expanding/extending or contracting along the plane 160, in a manner that is proportional to the acceleration so that the distance between the magnet 130 and the diamond sensor 140 changes. The change in distance can be described as d=ma/k where m is the mass of the magnet 130, a is the acceleration and k is the Hooke's constant of the spring 110.

In the example of FIG. 5 the mass 530 is displaced by a distance d_{acc} to a position 590 due to extension of the spring 510. When undergoing acceleration, the displacement distance (d_{acc}) of the magnet 530 from the initial rest position is related to the magnitude of the mass (m) of the magnet 530, the acceleration (a) experienced by the magnet 530 and the spring constant (k) of the spring 510 by Equation (1) below

$${d}_{a c c} = ma / k \qquad ( 1 )$$

The strength of the magnetic field at the diamond sensor 540 varies according to an inverse square law, that is, magnetic field B is proportional to 1/d_{sig}².As shown in the example of FIG. 5, d_{sig} is the distance from the magnet 530 to the diamond sensor 540 after displacement to the position 590. The relationship between magnetic field and distance enables measurement of acceleration from the magnetic field strength.

Given that the magnet 530 has known properties, the magnetic flux (B) at the position of a diamond sensor 540 at the initial distance (d_{ref}) away from the magnet 530 can be determined by measuring the frequency shift (Δv) (Zeeman shift) in the magnetic resonance spectrum of the nitrogen-vacancy centres of the diamond sensor. The magnitude of the frequency shift is directly related to the change in magnetic flux along the axis of the nitrogen-vacancy centre by the known relationship Δv/ΔB=28 Hz/nano-Tesla (see Acosta, V. et al. Phys Rev Lett 104, 070801 (2010)). Therefore, by measuring the change in magnetic flux (ΔB) as the magnet 530 moves when undergoing acceleration (a), the displacement (d_{acc}) of the mass from its rest position (d_{ref}) can be determined using Equation (2) below:

$${B}_{s i g} = {B}_{ref} ( {d}_{ref}^{2} / {d}_{s i g}^{2} ) \qquad ( 2 )$$

In Equation (2) d_{sig} is the distance of the magnetic mass from the sensor under acceleration (d_{sig}=d_{ref}−d_{acc}). The acceleration (a) that causes the displacement (d_{acc}) can be determined by the relationship a=d_{acc} k/m from Equation (1).

Referring to FIG. 3, the dataflow 300 continues from step 330 to a magnetic field variation step 340. At step 340 the movement of the magnet 530 relative to the diamond sensor 540 means that the magnetic field experienced by the diamond sensor 540 is altered. Alteration or variation in the magnetic field causes a shift in the magnetic resonance spectrum of the NV centres (Zeeman shift) and a change in the fluorescence generated by the diamond sensor 540 when the microwave field is resonant with the spectral features. The change in magnetic field results in a corresponding change in fluorescence emitted by the diamond sensor 540.

Referring to FIG. 3, the dataflow 300 continues from step 340 to an electrical signal generation step 350. At step 350, the changing fluorescence generated by the diamond sensor 540 is sensed by the optical sensor 255. A corresponding variation in an electrical signal, such as voltage, generated by the sensor 255 is amplified by the amplifier 270. The generated electrical signal varies in a manner that allows measurement of the position of the magnetic resonance features in the diamond sensor 540, which, change depending on the strength of an applied magnetic field. A change in the magnetic field causes a Zeeman shift of a certain frequency (Δv). The magnitude of the shift can be ascertained by adjusting the frequency of the RF microwave control field to the point where the frequency of the field is resonant with the spectral features of the diamond 540, and a corresponding reduction in fluorescence is observed. The frequency of the RF field can be adjusted using a feedback loop implemented in the system 200, either in software or in hardware, for example by operation of the processing system 280 in association with the RF system 220. The feedback loop would continually measure the fluorescence from the nitrogen vacancy centre as a function of the applied RF field 170. Any change in the magnetic field being sensed causes the fluorescence intensity as a function of the applied RF field to change. The magnetic field can thus be determined because the Zeeman shift due to a magnetic field applied along the nitrogen-vacancy symmetry axis is known to be 28 Hz/nano-Tesla (see: Acosta, V. et al. Phys Rev Lett 104, 070801 (2010)). The altered magnetic field, B_{sig}, can be represented using Equation (3) below:

$${B}_{s i g} = [ \frac{( {v}_{sig} - {v}_{ref} )}{28 Hz / nT} ] + {B}_{ref} \qquad ( 3 )$$

Equation (3) above is based on the Zeeman effect represented by Equation (4)

$$Δ v ( Zeeman ) = \frac{28 Hz}{nT} \qquad ( 4 )$$

The dataflow 300 continues from step 350 to an acceleration determination step 360. At step 360 the measurement of the magnetic field B_{sig} is received by the processing system 280. The processing system 280 uses the measurement to determine the distance d_{sig} of the magnet 530 from the sensor 540 based on the inverse square law, for example as represented in Equation (5)

$${d}_{s i g} = {d}_{r e f} \sqrt{\frac{{B}_{ref}}{{B}_{sig}}} \qquad ( 5 )$$

The displacement d_{acc} of the magnet 530 due to acceleration can be determined according to d_{acc}=d_{ref}−d_{sig}.

The acceleration which caused the displacement is determined by the processing system 280 using Equation (6):

$$a = \frac{{a}_{a c c} \times k}{m} \qquad ( 6 )$$

Equations (1) to (6) can be summarised using Equation (7)

$$a = k \times \frac{( {d}_{r e f} - {d}_{r e f} \frac{{B}_{r e f}}{s + {B}_{r e f}} )}{m} \qquad ( 7 )$$

In Equation (7), s can be represented based on Equation (3) as

$$\frac{( {v}_{sig} - {v}_{ref} )}{28 Hz / nT} .$$

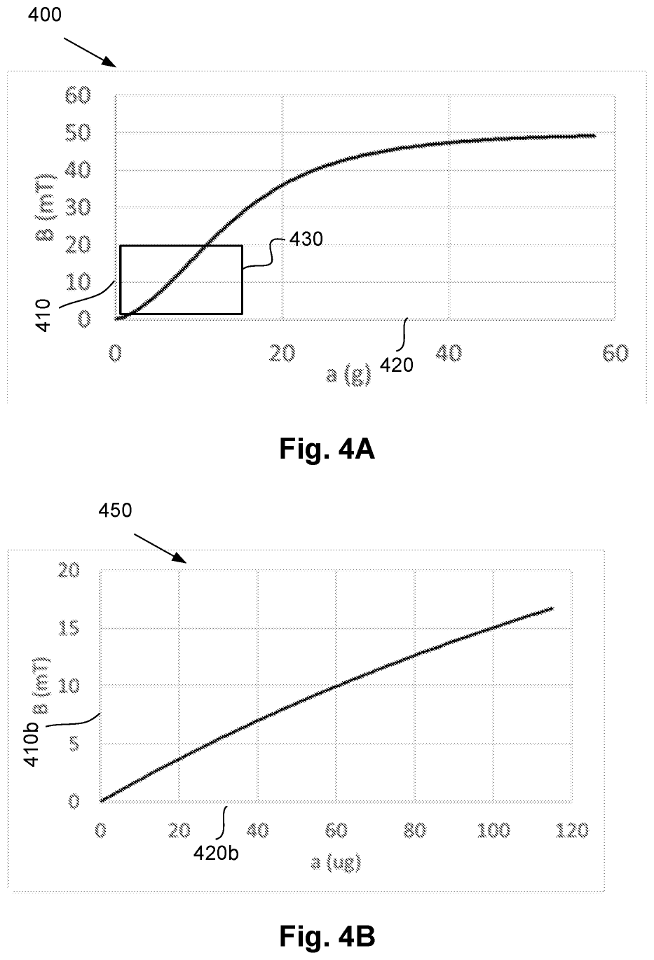

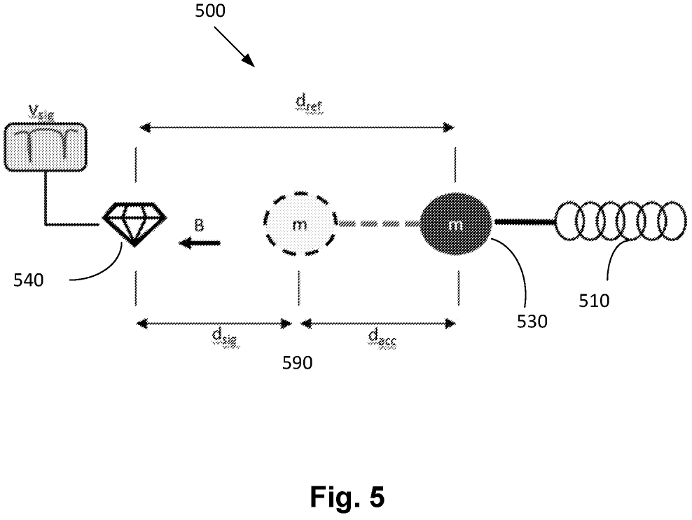

FIG. 4A shows a graph 400 showing an example relationship between change in magnetic field (on a y-axis 410) and acceleration (on an x-axis 420). An area 430 shows a range in which the relationship between magnetic field and acceleration can be modelled.

FIG. 4B shows a graph 450 providing an enlarged view of the area 430 of FIG. 4A. In the example of FIG. 4B, the relationship between change in magnetic field (y-axis 410b) and acceleration (x-axis 420b) can be modelled using techniques such as best fit algorithms, tracking algorithms, averaging techniques and the like. The relationship enables measuring acceleration over a range that is relevant for navigation using inertial measurement units.

In the example of FIG. 1B, the distance between the magnet 130 and the diamond 140 changes as magnet 130 moves relative to the diamond sensor 140 in response to acceleration. In particular, in the example of FIG. 1B the diamond sensor 140 has a fixed position.

Some alternative arrangements can be used to implement an accelerometer, as described below.

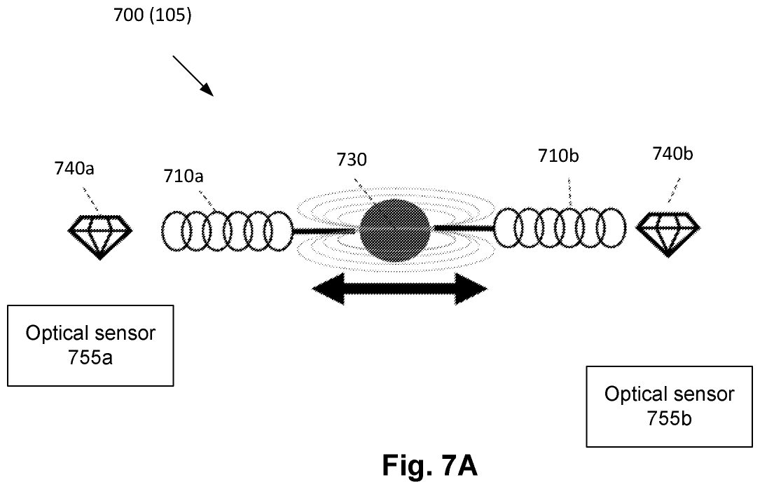

FIG. 6 shows an alternative arrangement 600 of the sensor 105. The arrangement 600 includes a magnet 630, a spring 610 and a diamond sensor 640. The magnet 630, spring 610 and diamond sensor 640 are similar to the magnet 130, spring 110 and diamond sensor 140 of FIG. 1B. In contrast to the system 105, in the arrangement 600 the magnet 630 has a fixed position and does not move based on deformation (such as extension or contraction) of the spring 610 in response to acceleration. Rather, the diamond sensor 640 is attached to the spring 610 and can move relative to the magnet 630 as the spring 610 deforms or returns towards an original shape.

The arrangement 600 is initialised as at step 310 with the diamond sensor 640 illuminated and in presence of a resonant RF field. An initial magnetic field measurement is taken as described at step 320. Accordingly, for the system 600, at step 330, acceleration causes a change or variation in distance between the magnet relative to the diamond sensor 640 due to movement of the diamond 640 as the spring 610 expands or contracts, thereby causing a variation or alteration in the magnetic field experienced by the diamond 640 at step 340.

Whether the magnet is attached to a spring (FIG. 1A, FIG. 5) or the spring is attached to the sensor (FIG. 6), acceleration causes a distance between the magnet and the sensor to change, thereby resulting in variation of a magnetic field experienced by the diamond sensor. Fluorescence emitted by the NV centre diamond resultantly changes. The change in fluorescence allows the acceleration to be determined as described in relation to steps 340 to 360 of FIG. 3.

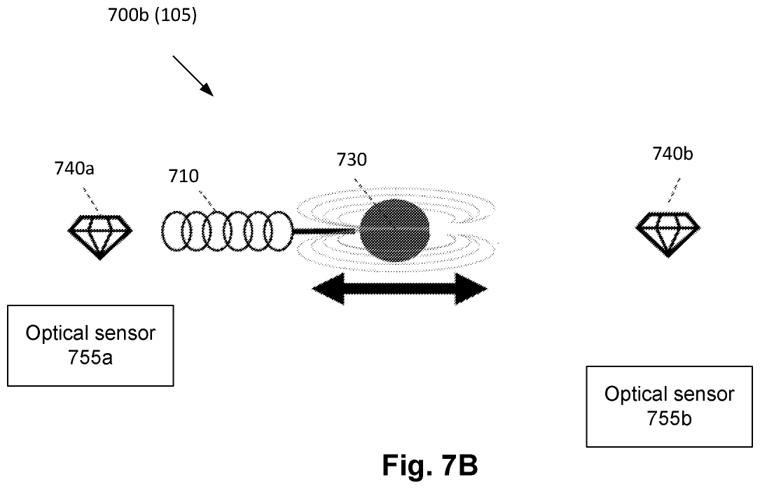

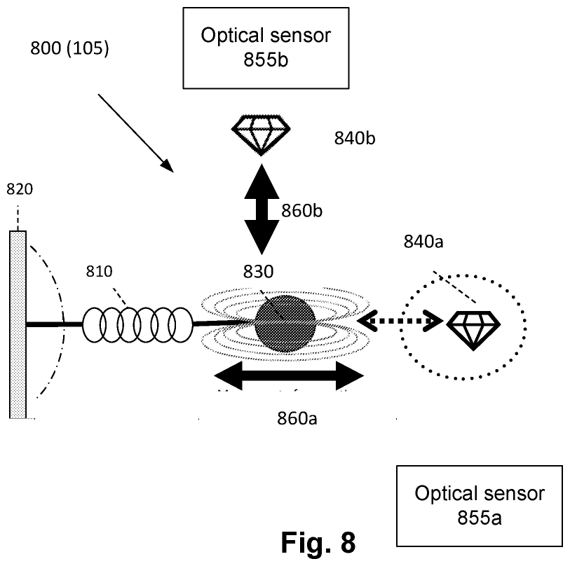

In some implementations, multiple diamond sensor elements can be used. Use of multiple sensor elements can be beneficial in some instances in order to remove background noise fluctuations experienced by the accelerometer device and/or to implement a differential signal configuration. FIG. 7A shows an example system 700 comprising a mass 730, two springs 710a and 710b and two diamond sensors 740a and 740b. The mass 730 is similar to the mass 130, the springs 710a and 710b are each similar to the spring 110 and the diamond sensors 740a and 740b are similar to the diamond sensor 140. Alternatively a single spring may be used as shown by an example system 700b. the system 700b is the same as the system 700 except the system 700b uses a single spring 710 instead of the pair of springs 710a and 710b.

Returning to FIG. 7A, the arrangement 700 is initialised as at step 310 with both sensors 740a and 740b illuminated and in presence of an RF field. An initial magnetic field measurement, influenced by the magnet 730 is taken for each of the sensors 740a and 740b as described at step 320.

When acceleration is applied to the accelerometer system using the implementation of FIG. 7A at step 330, the magnet 730 is displaced relative to both diamond sensing elements 740a and 740b by coiling and releasing of the associated springs 710a and 710b. Effectively a distance between the magnet 730 varies in relation to each of first and second diamonds (740a and 740b). At step 340, a variation in magnetic field is associated with each of the diamond sensors 740a and 740b. Both of the diamond sensors 740a and 740b are optically illuminated and placed in presence of a radio frequency field by operation of the control and readout system 200. The control and readout system can include an optical sensor for each diamond sensor for example.

When one diamond sensor, for example 740b, senses a decrease in magnetic field because the magnetic mass is moving away from it under acceleration, the other sensor, 740a will experience a complementary change in magnetic field due to the magnet 730 moving toward the second sensor. Variation in fluorescence of the first diamond sensor (710a for example) and the second diamond sensor and sensed by an optical sensor 755 (corresponding to the 255) of the control and readout system and used to determined acceleration as described in relation to steps 350 to 360 above. This differential detection implementation can yield a further improved signal to noise ratio, reducing effects of noise.

The system 700b operates in a similar manner to the system 700 above in relation to steps 310 and 320. When acceleration is applied to the accelerometer system using the implementation of FIG. 7B at step 330, the magnet 730 is displaced relative to both diamond sensing elements 740a and 740b by coiling and releasing of the spring 710 in response to the acceleration force. Effectively a distance between the magnet 730 varies in relation to each of first and second diamonds (740a and 740b). Acceleration is determined as described in relation to steps 340 to 360 above.

The systems 105 of FIG. 1B, 600 of FIGS. 6 and 700 and 700b of FIGS. 7A and 7B relate to detecting acceleration in a single plane or dimension, such as the plane 160, where the movement of the magnetic mass 130 on a spring is measured in one dimension only. That is, measurements of change in distance in the same plane are used for the first and second diamond sensors 710a and 710b.

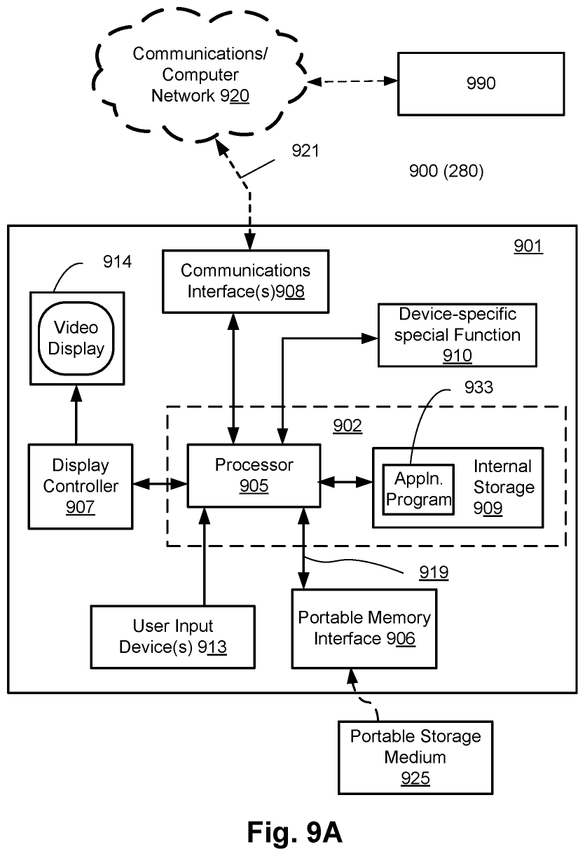

In other implementations using multiple diamond sensors, movement of a magnet relative to multiple diamond sensors can be measured in more than one plane. FIG. 8 shows an example arrangement 800 using more than one NV diamond to determine acceleration.

The arrangement 800 comprises a mass 830, a spring 810 and two diamond sensors 840a and 840b. The mass 830 is similar to the mass 130, the spring 810 is similar to the spring 110 and the diamond sensors 840a and 840b are each similar to the diamond sensor 140. The arrangement 800 is initialised as at step 310 with both sensors 840a and 840b illuminated and in presence of an RF field. An initial magnetic field measurement is taken as at step 320.

When acceleration is applied to the accelerometer system using the implementation of FIG. 8 at step 330 the magnet 830 can be displaced relative to both diamond sensing elements 840a and 840b by compression and extension of the spring 810a in response to the acceleration. Effectively a distance between the magnet 830 varies in relation to each of first and second diamond sensors (840a and 840b). At step 340, a magnetic field variation associated with each of the diamond sensors 840a and 840b is determined. Both of the diamond sensors 840a and 840b are optically illuminated and placed in presence of a radio frequency field by operation of the control and readout system 200. The control and readout system can include two implementations of the arrangements 250 for example. The processing system 280 can be common to both implementations of the arrangement 250 in some instances.

As acceleration occurs, the spring 810 experiences force and deforms accordingly. A distance between the magnet 830 and each of the first and second diamond sensors (840a and 840b) changes based on the motion of the spring 810. A resultant variation in magnetic field experienced by the diamond 840a is detected by an optical sensor 855a (corresponding to the at least one sensor 255) of the control and readout system 200 and used to determine acceleration of the mass relative to the sensor 840a as described in relation to steps 330 to 360. A resultant variation in magnetic field experienced by the diamond 840b is detected by an optical sensor 855b (corresponding to the at least one sensor 255) of the control and readout system 200 and used to determine acceleration of the mass relative to the sensor 840b as described in relation to steps 330 to 360.

In the example of FIG. 8, the diamond sensor 840b is used to determine acceleration due to motion of the magnet 830 in a plane perpendicular to motion between the magnet 830 and the diamond 840a (similar to a y-axis and an x-axis). The acceleration in each dimension can be used for tracking motion of a body in more than on direction as implemented using existing inertial navigation systems.

In some implementations, movement in different dimensions could be measured simultaneously by exploiting the four (4) unique orientations of NV centres in the diamond lattice or by utilising multiple sensor elements arranged around the magnetic mass on a spring.

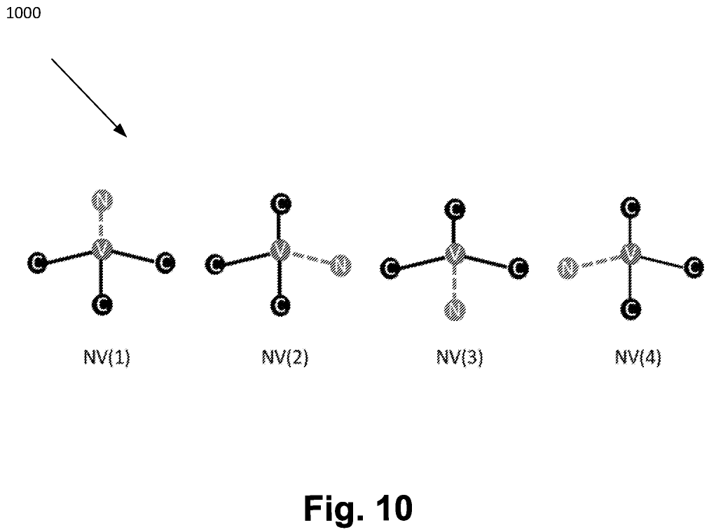

FIG. 10 shows a collection 1000 of example crystalline structures of NV centre diamond. Each of structures NV(1) to NV(4) includes carbon atoms marked “C” and a nitrogen-vacancy connection “N” to “V”. The nitrogen-vacancy direction of each of NV(1) to NV(4) is along a different direction of the tetrahedral diamond lattice. In a given diamond crystal, such as the sensor 140, all NV centres are typically randomly distributed along the 4 connections shown by NV(1) to NV(4). Accordingly, each measurement includes responses in four different directions to the change in magnetic field as a magnet (such as 130) moves toward or away from the diamond sensor. The four components, or vectors, are reflected in the single, overall response of the diamond. Use of diamond sensors arranged in multiple planes relative to a magnetic field vector can enable accurate construction of the net field vector by reading the Zeeman shift of each of the four NV centre orientations separately which, when combined in magnitude and direction yield the overall magnetic field vector.

As described above, the processing system 280 can be implemented as part of an integrated microchip including a microprocessor or FPGA may relate to an external device.

FIGS. 9A and 9B collectively form a schematic block diagram of an example external general purpose electronic device 901 including embedded components, upon which the methods implemented by the processing system 280 can be practiced. The electronic device 901 may be, for example, a mobile phone or tablet, in which processing resources are limited. Nevertheless, the methods to be described may also be performed on higher-level devices such as desktop computers, server computers, and other such devices with significantly larger processing resources.

In the example of FIG. 9A, the device 901 is in communication with a system 990. The system 990 includes the acceleration system 105 and components of the control and readout system 200 other than the processing system 280.

As seen in FIG. 9A, the electronic device 901 comprises an embedded controller 902. Accordingly, the electronic device 901 may be referred to as an “embedded device.” In the present example, the controller 902 has a processing unit (or processor) 905 which is bi-directionally coupled to an internal storage module 909. The storage module 909 may be formed from non-volatile semiconductor read only memory (ROM) 960 and semiconductor random access memory (RAM) 970, as seen in FIG. 9B. The RAM 970 may be volatile, non-volatile or a combination of volatile and non-volatile memory.

The electronic device 901 includes a display controller 907, which is connected to a video display 914, such as a liquid crystal display (LCD) panel or the like. The display controller 907 is configured for displaying graphical images on the video display 914 in accordance with instructions received from the embedded controller 902, to which the display controller 907 is connected.

The electronic device 901 also includes user input devices 913 which are typically formed by keys, a keypad or like controls. In some implementations, the user input devices 913 may include a touch sensitive panel physically associated with the display 914 to collectively form a touch-screen. Such a touch-screen may thus operate as one form of graphical user interface (GUI) as opposed to a prompt or menu driven GUI typically used with keypad-display combinations. Other forms of user input devices may also be used, such as a microphone (not illustrated) for voice commands or a joystick/thumb wheel (not illustrated) for ease of navigation about menus.

As seen in FIG. 9A, the electronic device 901 also comprises a portable memory interface 906, which is coupled to the processor 905 via a connection 919. The portable memory interface 906 allows a complementary portable memory device 925 to be coupled to the electronic device 901 to act as a source or destination of data or to supplement the internal storage module 909. Examples of such interfaces permit coupling with portable memory devices such as Universal Serial Bus (USB) memory devices, Secure Digital (SD) cards, Personal Computer Memory Card International Association (PCMIA) cards, and the like.

The electronic device 901 also has a communications interface 908 to permit coupling of the device 901 to a computer or communications network 920 via a connection 921. The connection 921 may be wired or wireless. For example, the connection 921 may be radio frequency or optical. An example of a wired connection includes Ethernet. Further, an example of wireless connection includes Bluetooth™ type local interconnection, Wi-Fi (including protocols based on the standards of the IEEE 802.11 family), Infrared Data Association (IrDa) and the like. The electronic signal generated at step 350 may be communicated from the system 990 to the device 901 via the network 920 for example.

Typically, the electronic device 901 is configured to perform some special function. The embedded controller 902, possibly in conjunction with further device-specific special function components 910, is provided to perform that special function. For example, where the device 901 is a digital camera, the components 910 may represent a lens, focus control and image sensor of the camera. The special function components 910 is connected to the embedded controller 902. As another example, the device 901 may be a mobile telephone handset. In this instance, the components 910 may represent those components required for communications in a cellular telephone environment. Where the device 901 is a portable device, the special function components 910 may represent a number of encoders and decoders of a type including Joint Photographic Experts Group (JPEG), (Moving Picture Experts Group) MPEG, MPEG-1 Audio Layer 3 (MP3), and the like.

The methods described hereinafter may be implemented using the embedded controller 902, where the processes described in relation to step 360 may be implemented as one or more software application programs 933 executable within the embedded controller 902. The electronic device 901 of FIG. 9A implements the described methods. In particular, with reference to FIG. 9B, the steps of the described methods are effected by instructions in the software 933 that are carried out within the controller 902. The software instructions may be formed as one or more code modules, each for performing one or more particular tasks. The software may also be divided into two separate parts, in which a first part and the corresponding code modules performs the described methods and a second part and the corresponding code modules manage a user interface between the first part and the user.

The software 933 of the embedded controller 902 is typically stored in the non-volatile ROM 960 of the internal storage module 909. The software 933 stored in the ROM 960 can be updated when required from a computer readable medium. The software 933 can be loaded into and executed by the processor 905. In some instances, the processor 905 may execute software instructions that are located in RAM 970. Software instructions may be loaded into the RAM 970 by the processor 905 initiating a copy of one or more code modules from ROM 960 into RAM 970. Alternatively, the software instructions of one or more code modules may be pre-installed in a non-volatile region of RAM 970 by a manufacturer. After one or more code modules have been located in RAM 970, the processor 905 may execute software instructions of the one or more code modules.

The application program 933 is typically pre-installed and stored in the ROM 960 by a manufacturer, prior to distribution of the electronic device 901. However, in some instances, the application programs 933 may be supplied to the user separately and stored in the internal storage module 909 or in the portable memory 925. For example, the software application program 933 may be read by the processor 905 from the network 920, or loaded into the controller 902 or the portable storage medium 925 from computer readable media. Computer readable storage media refers to any non-transitory tangible storage medium that participates in providing instructions and/or data to the controller 902 for execution and/or processing. Examples of such storage media include a hard disk drive, a ROM or integrated circuit, USB memory, a magneto-optical disk, flash memory, or a computer readable card such as a PCMCIA card and the like, whether or not such devices are internal or external of the device 901. Examples of transitory or non-tangible computer readable transmission media that may also participate in the provision of software, application programs, instructions and/or data to the device 901 include radio or infra-red transmission channels as well as a network connection to another computer or networked device, and the Internet or Intranets including e-mail transmissions and information recorded on Websites and the like. A computer readable medium having such software or computer program recorded on it is a computer program product.

The second part of the application programs 933 and the corresponding code modules mentioned above may be executed to implement one or more graphical user interfaces (GUIs) to be rendered or otherwise represented upon the display 914 of FIG. 9A. Through manipulation of the user input device 913 (e.g., the keypad), a user of the device 901 and the application programs 933 may manipulate the interface in a functionally adaptable manner to provide controlling commands and/or input to the applications associated with the GUI(s). Other forms of functionally adaptable user interfaces may also be implemented, such as an audio interface utilizing speech prompts output via loudspeakers (not illustrated) and user voice commands input via the microphone (not illustrated).

FIG. 9B illustrates in detail the embedded controller 902 having the processor 905 for executing the application programs 933 and the internal storage 909. The internal storage 909 comprises read only memory (ROM) 960 and random access memory (RAM) 970. The processor 905 is able to execute the application programs 933 stored in one or both of the connected memories 960 and 970. When the electronic device 901 is initially powered up, a system program resident in the ROM 960 is executed. The application program 933 permanently stored in the ROM 960 is sometimes referred to as “firmware”. Execution of the firmware by the processor 905 may fulfil various functions, including processor management, memory management, device management, storage management and user interface.

The processor 905 typically includes a number of functional modules including a control unit (CU) 951, an arithmetic logic unit (ALU) 952, a digital signal processor (DSP) 953 and a local or internal memory comprising a set of registers 954 which typically contain atomic data elements 956, 957, along with internal buffer or cache memory 955. One or more internal buses 959 interconnect these functional modules. The processor 905 typically also has one or more interfaces 958 for communicating with external devices via system bus 981, using a connection 961.

The application program 933 includes a sequence of instructions 962 though 963 that may include conditional branch and loop instructions. The program 933 may also include data, which is used in execution of the program 933. This data may be stored as part of the instruction or in a separate location 964 within the ROM 960 or RAM 970.

In general, the processor 905 is given a set of instructions, which are executed therein. This set of instructions may be organised into blocks, which perform specific tasks or handle specific events that occur in the electronic device 901. Typically, the application program 933 waits for events and subsequently executes the block of code associated with that event. Events may be triggered in response to input from a user, via the user input devices 913 of FIG. 9A, as detected by the processor 905. Events may also be triggered in response to other sensors and interfaces in the electronic device 901.

The execution of a set of the instructions may require numeric variables to be read and modified. Such numeric variables are stored in the RAM 970. The disclosed method uses input variables 971 that are stored in known locations 972, 973 in the memory 970. The input variables 971 are processed to produce output variables 977 that are stored in known locations 978, 979 in the memory 970. Intermediate variables 974 may be stored in additional memory locations in locations 975, 976 of the memory 970. Alternatively, some intermediate variables may only exist in the registers 954 of the processor 905.

The execution of a sequence of instructions is achieved in the processor 905 by repeated application of a fetch-execute cycle. The control unit 951 of the processor 905 maintains a register called the program counter, which contains the address in ROM 960 or RAM 970 of the next instruction to be executed. At the start of the fetch execute cycle, the contents of the memory address indexed by the program counter is loaded into the control unit 951. The instruction thus loaded controls the subsequent operation of the processor 905, causing for example, data to be loaded from ROM memory 960 into processor registers 954, the contents of a register to be arithmetically combined with the contents of another register, the contents of a register to be written to the location stored in another register and so on. At the end of the fetch execute cycle the program counter is updated to point to the next instruction in the system program code. Depending on the instruction just executed this may involve incrementing the address contained in the program counter or loading the program counter with a new address in order to achieve a branch operation.

Each step or sub-process in the processes of the methods described below is associated with one or more segments of the application program 933, and is performed by repeated execution of a fetch-execute cycle in the processor 905 or similar programmatic operation of other independent processor blocks in the electronic device 901.

### INDUSTRIAL APPLICABILITY

Data from measurements of the signal generated by the optical sensor 255 can be processed as described in relation to operation of steps 340 to 360 to yield a real-time measurement of the acceleration vector that the mass 130 on the spring 110 is experiencing. As described in relation to FIGS. 7 and 8, multiple measurements can be made using multiple sensors for real-time measurement of an acceleration vector of a host vehicle.

The acceleration measurement can be used for a variety of applications. The acceleration system 100 (or a portion thereof such as the acceleration system 105) can be affixed to a host vehicle and used to measure acceleration. For example, the system 100 could be used to measure acceleration of a mining vehicle. The system 100 is initialised at step 310 when the mining machine is stopped and an initial magnetic field measured at step 320. The mining machine begins to accelerate and the distance between the magnet 130 and the diamond 140 varies as the spring 110 deforms or changes shape (for example expands or compresses) due to the acceleration. The magnetic field experienced by the diamond 140 varies as at step 340 and fluorescence emitted by the diamond 140 varies. The optical sensor 255 senses the variation and generates a corresponding electrical signal as described at step 350. The processing system 280 determines the acceleration from the generated electrical signal as described in relation to step 360.

For example, the acceleration may be transmitted to a navigation system that records acceleration vectors experienced by the magnetic mass 530 (and by inference, all acceleration vectors experienced by the vehicle the sensor is mounted to) to ascertain the net motion and relative position of the vehicle.

The arrangements described are applicable to the industries in which acceleration readings are used, for example navigation, mining, and civil engineering industries. As use of diamond with nitrogen-vacancy defects is less vulnerable to electromagnetic noise and vibrations than traditional accelerometer devices, the arrangements described are particularly suitable for applications which can be prone to noise and thereby reduce the likelihood of drift. Additionally, more than one diamond sensor can be used, as described in relation to FIGS. 7 and 8, which can further decrease effects of noise.

The foregoing describes only some embodiments of the present invention, and modifications and/or changes can be made thereto without departing from the scope and spirit of the invention, the embodiments being illustrative and not restrictive.

In the context of this specification, the word “comprising” means “including principally but not necessarily solely” or “having” or “including”, and not “consisting only of”. Variations of the word “comprising”, such as “comprise” and “comprises” have correspondingly varied meanings.

1. A system for measuring acceleration, comprising:
a diamond having a nitrogen-vacancy centre, whereby the diamond emits fluorescence under optical illumination in presence of a radio frequency field tuned to a resonant frequency of the nitrogen-vacancy centre,
a magnet having a known mass; and
an optical sensor; wherein
the system is configured such that a distance between the magnet and the diamond varies in response to acceleration of the system, the change in distance altering a magnetic field experienced by the diamond; and
the optical sensor is configured to sense variation in fluorescence emitted by the diamond in response to the altered magnetic field for measuring acceleration.

2. The system according to claim 1, further comprising a processor in communication with a memory, the memory storing instructions for execution on the processor to determine acceleration using the sensed variation in fluorescence.

3. The system according to claim 1, wherein the magnet is attached to a spring and the distance between the magnet and the diamond varies due to a change in shape of the spring in response to the acceleration.

4. The system according to claim 1, wherein the diamond is attached to a spring and the distance between the magnet and the diamond varies due to a change in shape of the spring in response to the acceleration.

5. The system according to claim 1, wherein the diamond is a first diamond, the system further comprising a second diamond having a nitrogen-vacancy centre configured to emit fluorescence under optical illumination in presence of the radio frequency field, wherein a distance between the magnet and the second diamond varies in response to acceleration of the system, the change in distance altering a magnetic field experienced by the second diamond when illuminated in presence of the radio frequency field.

6. The system according to claim 5, wherein the variation in distance between the magnet and the second diamond varies in a same plane as the variation in distance between the magnet and the first diamond.

7. The system according to claim 5, wherein the variation in distance between the magnet and the second diamond varies in a plane perpendicular to the variation in distance between the magnet and the first diamond.

8. The system according to claim 1, wherein the system is integrated into a single microchip.

9. The system according to claim 2, wherein the system is integrated into a single microchip.

10. The system according to claim 2, wherein the diamond, the magnet and the optical sensor form a single integrated device.

11. The system according to claim 10, wherein the sensed variation in fluorescence is transmitted to an external device for determining acceleration.

12. The system according to claim 3, wherein a range of movement in distance between the magnet and the diamond depends on the mass of the magnet and a constant of the spring.

13. A method for measuring acceleration, comprising
illuminating a diamond having a nitrogen-vacancy centre in presence of a radio frequency field tuned to a resonant frequency of the nitrogen-vacancy centre;
measuring an initial magnetic field experienced by the diamond;
sensing a variation in fluorescence emitted by the diamond if a distance between a magnet and the diamond varies in response to acceleration;
generating, by an optical sensor, an electrical signal corresponding to the variation in fluorescence;
determining using the generated signal, the acceleration.
